(19) United States
(12) Patent Application Publication
(10) Pub. No.: US 2026/0046560 A1
(43) Pub. Date: Feb. 12, 2026

(54) AUDIO SIGNAL PROCESSING METHOD AND AUDIO SIGNAL PROCESSING DEVICE

(71) Applicant: Tymphany HK Limited, Hong Kong (HK)

(72) Inventor: FU-DI LI, Taipei City (TW)

(21) Appl. No.: 18/799,342

(22) Filed: Aug. 9, 2024

(51) Int. Cl. H04R 3/00; G06F 3/16; H03F 3/183; H04R 3/04; H04S 1/00

(52) U.S. Cl. CPC H04R 3/007; G06F 3/162; H04R 3/04; H04S 1/007; H03F 3/183; H03F 2200/03; H04R 2430/01

(57) ABSTRACT

An audio signal processing method, and an audio signal processing device for executing the audio signal processing method includes, obtaining an audio signal and compressing the audio signal to generate a first compressed signal; calculating a duration for which a power value of the first compressed signal equals a first power threshold; determining whether the duration exceeds a first time threshold; when the duration exceeds the first time threshold, compressing the first compressed signal to generate a second compressed signal, and amplifying and outputting the second compressed signal.

### BACKGROUND

### 1. Technical Field

The present application relates to the technical field of audio signal processing, particularly to an audio signal processing method and an audio signal processing device.

### 2. Description of the Related Art

With the rapid advancement of technology, audio signal processing has transitioned from analog audio signal processing to digital audio signal processing.

In digital audio signal processing, compressors/limiters are typically used in speaker systems to compress the dynamic range of digital audio signals and control the power of digital audio signals. This helps to prevent unpleasant sounds such as howling and noise. However, when the speaker system operates at full power input for an extended period, or when the digital audio signals output by the speaker system exceed the system's maximum power capacity, it can easily damage the speaker system's power amplifier or speakers. Under extreme conditions, there is a possibility that electronic components within the speaker system may emit smoke or catch fire, directly affecting consumer safety and experience.

### SUMMARY OF THE INVENTION

Based on the above, the present application provides an audio signal processing method and an audio signal processing device to address the issue of damage to the power amplifier or speakers in a speaker system when it operates at full power input for extended periods

Based on the above, the present application provides an audio signal processing method executed by an audio signal processing device, including: obtaining an audio signal and compressing the audio signal to generate a first compressed signal, wherein the power value of the first compressed signal is less than or equal to a first power threshold; calculating the duration for which the power value of the first compressed signal equals the first power threshold; determining whether the duration exceeds a time threshold; when the duration exceeds the time threshold, compressing the first compressed signal to generate a second compressed signal, and amplifying and outputting the second compressed signal, wherein the power value of the second compressed signal is less than or equal to a second power threshold, and the second power threshold is less than the first power threshold.

Based on the above, the present application provides an audio signal processing device, comprising a first limiter, a processor, a second limiter, a limiting trigger time component, and a power amplifier. The first limiter obtains an audio signal and compresses the audio signal to generate a first compressed signal, wherein the power value of the first compressed signal is less than or equal to a first power threshold. The limiting trigger time component is connected to the first limiter, calculates the duration for which the power value of the first compressed signal equals the first power threshold, and determines whether the duration exceeds a time threshold. The second limiter is connected to the limiting trigger time component and, when the limiting trigger time component determines that the duration exceeds the time threshold, compresses the first compressed signal to generate a second compressed signal. The power value of the second compressed signal is less than or equal to a second power threshold, and the second power threshold is less than the first power threshold. The power amplifier is connected to the second limiter and the first limiter, and amplifies and outputs the second compressed signal.

In summary, the audio signal processing method and the audio signal processing device provided by the present application, by configuring two limiters, reduce excessively loud sounds and prevent damage to electronic components when the speaker system operates at maximum power for extended periods.

Additionally, the audio signal processing method and the audio signal processing device provided by the present application can be applied to subwoofer systems. Even when the subwoofer system operates at high power for extended periods, the present audio signal processing method and device can prevent damage to the speakers and the power amplifier caused by high power operation, without affecting the ability to output large dynamic signals for short periods.

Other objectives, features and advantages of the present invention will be further understood from the further technological features disclosed by the embodiments of the present invention wherein there are shown and described preferred embodiments of the present invention, simply by way of illustration of modes best suited to carry out the invention.

### BRIEF DESCRIPTION OF THE DRAWINGS

The accompanying drawings presented herein serve to deepen the understanding of the present application and are an integral part thereof. The illustrative embodiments and their explanations are provided to elucidate the present application and do not impose any undue limitations on it. In the drawings:

FIG. 1 is a block diagram illustrating an audio signal processing device according to an embodiment of the present application;

FIG. 2 is a flowchart illustrating an audio signal processing method according to an embodiment of the present application;

FIG. 3 is a flowchart illustrating an audio signal processing method according to another embodiment of the present application;

FIG. 4A is a schematic diagram illustrating the output of the second compressed signal in the audio signal processing method according to another embodiment of the present application;

FIG. 4B is a schematic diagram illustrating the output of the first compressed signal in the audio signal processing method according to another embodiment of the present application;

FIG. 5 is a block diagram illustrating an audio signal processing device according to another embodiment of the present application; and

FIG. 6 is a schematic diagram illustrating the second limiter reducing the power of the audio signal according to an embodiment of the present application.

### DETAILED DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

The audio signal processing device of present application includes a first limiter, a limiting trigger time component, a second limiter, and a power amplifier. The first limiter obtains an audio signal and compresses audio signal to generate a first compressed signal, wherein the power value of the first compressed signal is less than or equal to a first power threshold. The limiting trigger time component is connected to the first limiter and calculates a duration for which the power value of the first compressed signal equals the first power threshold, and determines whether the duration exceeds a time threshold. The second limiter is connected to the limiting trigger time component and compresses the first compressed signal to generate a second compressed signal when the limiting trigger time component determines that the duration exceeds the time threshold. The power value of the second compressed signal is less than or equal to a second power threshold, the second power threshold is less than the first power threshold. The power amplifier is connected to the second limiter and the first limiter, and amplifies and outputs the second compressed signal. By using the limiting trigger time component and the second limiter, the device selectively compresses the first compressed signal to prevent damage to the speaker or power amplifier. Detailed embodiments are described below.

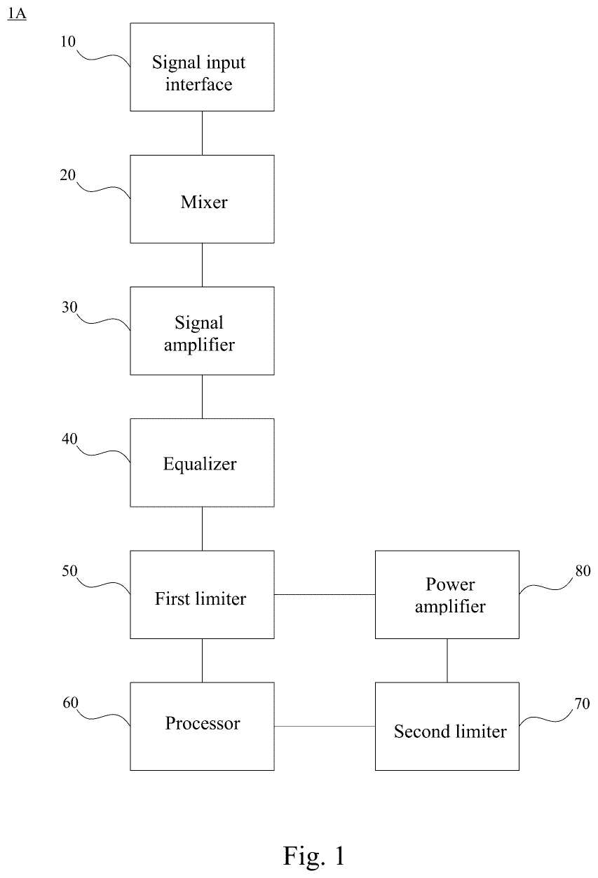

FIG. 1 is a block diagram illustrating an audio signal processing device according to an embodiment of the present application. As shown in FIG. 1, the audio signal processing device 1A is used for a speaker system and includes a signal input interface 10, a mixer 20, a signal amplifier 30, an equalizer 40, a first limiter 50, a processor 60, a second limiter 70, and a power amplifier 80.

The signal input interface 10 obtains a mono audio signal. Specifically, the signal input interface 10 is an input interface with multiple audio jacks and multiple USB (Universal Serial Bus) ports. The signal input interface 10 connects to audio playback devices, such as portable playback devices or microphones, via audio cables or USB cables to obtain the mono audio signal. Portable playback devices can include CD players, mobile phones, MP3 players, etc. In this embodiment, the audio signal processing device 1 further includes a mixer 20, which is connected to the signal input interface 10 and the signal amplifier 30. In other words, the mixer 20 is located between the signal input interface 10 and the signal amplifier 30. The audio playback device transmits a left channel audio signal and a right channel audio signal to the signal input interface 10 through audio or USB cables. The signal input interface 10 then transmits these left channel audio signal and the right channel audio signal to the mixer 20. The mixer 20 combines the left channel audio signal and the right channel audio signal into a mono audio signal and transmits this mono audio signal to the signal amplifier 30. In another embodiment, the audio playback device directly transmits the mono audio signal to the signal input interface 10 through audio or USB cables. The signal input interface 10 then transmits the mono audio signal to the signal amplifier 30.

The signal amplifier 30 is connected to the signal input interface 10. For example, the signal amplifier 30 can be an operational amplifier, a voltage amplifier, or a differential amplifier. In this embodiment, the signal amplifier 30 is connected to the signal input interface 10 through the mixer 20, obtaining the mono audio signal from the mixer 20 and amplifying it to generate an amplified audio signal. In another embodiment, the signal amplifier 30 is directly connected to the signal input interface 10, obtaining the mono audio signal from the signal input interface 10 and amplifying the mono audio signal to generate an amplified audio signal. Through the action of the signal amplifier 30, the amplitude of the amplified audio signal (e.g., voltage amplitude) is greater than that of the mono audio signal.

The equalizer 40 is connected to the signal amplifier 30; in other words, the signal amplifier 30 is positioned between the equalizer 40 and the mixer 20, or between the equalizer 40 and the signal input interface 10. Specifically, the equalizer 40 can be a multi-band variable equalizer, a linear equalizer, a decision feedback equalizer, or another type of equalizer. The equalizer 40 performs equalization processing on the amplified audio signal to generate a balanced audio signal. The details of the equalization process are further explained in the section describing the audio signal processing method.

The first limiter 50 is connected to the equalizer 40, the power amplifier 80, and the processor 60; in other words, the first limiter 50 is positioned between the equalizer 40 and the processor 60, as well as between the power amplifier 80 and the equalizer 40. For example, the first limiter 50 can be a voltage-controlled amplifier (VCA) compressor, a field-effect transistor (FET) compressor, a tube compressor, an optical compressor, or another type of compressor. The first limiter 50 has a first power threshold. In this embodiment, the balanced audio signal serves as the audio signal received by the first limiter 50. The first limiter 50 compresses the balanced audio signal to generate a first compressed signal, where the power value of the first compressed signal is less than or equal to the first power threshold. The details of generating the first compressed signal will be explained in the section describing the audio signal processing method. In another embodiment, the configuration of the equalizer 40 and the signal amplifier 30 may be omitted, and the mono audio signal serves as the audio signal received by the first limiter 50. The first limiter 50 compresses the mono audio signal to generate the first compressed signal. It should be noted that the audio signal received by the first limiter 50 can be any type of audio signal, and the type of audio signal received by the first limiter 50 is not limited in present application.

The processor 60 is connected to the second limiter 70, and the power amplifier 80 is connected to both the second limiter 70 and the first limiter 50. In other words, the second limiter 70 is positioned between the processor 60 and the power amplifier 80, and the power amplifier 80 is positioned between the second limiter 70 and the first limiter 50. For example, the processor 60 can be a microcontroller unit (MCU), a central processing unit (CPU), or another type of processor. The second limiter 70 can be a voltage-controlled amplifier (VCA) compressor, a field-effect transistor (FET) compressor, a tube compressor, an optical compressor, or another type of compressor. The power amplifier 80 can be a Class A amplifier, Class B amplifier, Class AB amplifier, Class C amplifier, Class D amplifier, or another type of amplifier.

In this embodiment, the processor 30 calculates the duration for which the power value of the first compressed signal equals the first power threshold and determines whether this duration exceeds the first time threshold to generate a determination result. The second limiter 70 has a second power threshold. Subsequently, based on the determination result, the processor 30 controls the first limiter 50 to output the first compressed signal to either the power amplifier 80 or the second limiter 70. The second limiter 70 further compresses the first compressed signal to generate a second compressed signal, with the power value of the second compressed signal being less than or equal to the second power threshold. Finally, the power amplifier 80 amplifies and outputs either the first compressed signal or the second compressed signal to the audio playback device. The details of determining the duration and selecting either the first compressed signal or the second compressed signal for amplification and output will be described in the audio signal processing method section.

In another embodiment, the processor 30 calculates the duration for which the power value of the first compressed signal equals the first power threshold and determines whether this duration exceeds the first time threshold to generate a first determination result. The second limiter 70 has a second power threshold. Subsequently, based on the first determination result, the processor 30 controls the first limiter 50 to output the first compressed signal to either the power amplifier 80 or the second limiter 70. When the processor 30 transmits the first compressed signal to the second limiter 70, the processor 30 calculates the entry time of the first compressed signal into the second limiter 70 and determines whether this entry time exceeds the second time threshold to generate a second determination result. Based on the second determination result, the processor 30 selectively activates the second limiter 70 to further compress the first compressed signal, resulting in the second compressed signal, with the power value of the second compressed signal being less than or equal to the second power threshold. Finally, the power amplifier 80 amplifies and outputs either the first compressed signal or the second compressed signal to the audio playback device. The details of determining the duration, entry time, and generating the second compressed signal will be described in the audio signal processing method section.

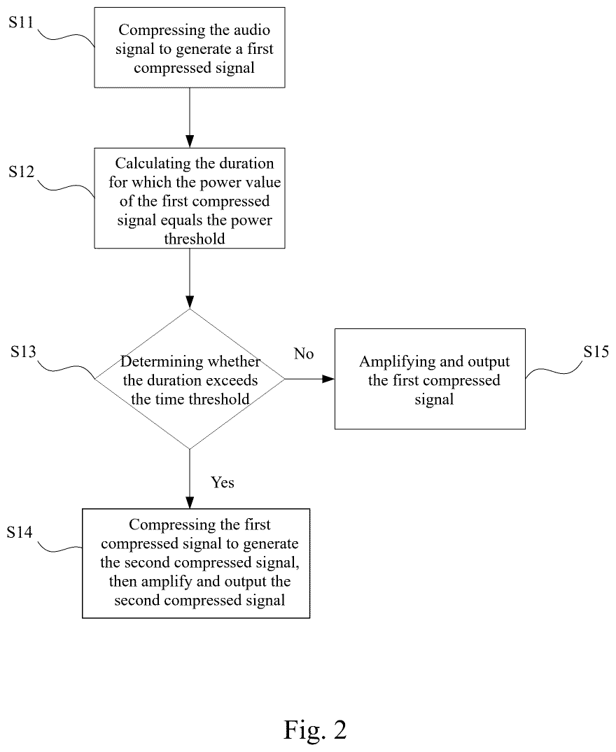

FIG. 2 illustrates a flowchart of an audio signal processing method according to one embodiment of the present application. As shown in FIG. 2, the audio signal processing method includes steps S11 to S15. The audio signal processing method shown in FIG. 2 can be applied to the audio signal processing device that includes the first limiter, the limiting trigger time component, the second limiter, and the power amplifier, or the audio signal processing device 1A shown in FIG. 1, but is not limited thereto. The following steps S11 to S15 are illustratively explained using the audio signal processing device 1A shown in FIG. 1.

Step S11: Compressing the audio signal to generate a first compressed signal. Specifically, the first limiter 50 compresses the audio signal based on a first attack time, a first release time, a first compression threshold, and a first compression ratio. The maximum signal level of the compressed audio signal is lower than the first compression threshold. The compressed audio signal is referred to as the first compressed signal, which has a dynamic range smaller than that of the audio signal, and the power value of the first compressed signal is less than or equal to the first power threshold. Additionally, the first attack time, first release time, first compression threshold, and first compression ratio are preset in the first limiter 50. The amplified audio signal, the mono audio signal, or other types of audio signals can be received by the first limiter 50 as the audio signal, and the type of audio signal received by the first limiter 50 is not limited in present application.

When the audio signal exceeds the threshold, the limiter starts to compress the audio signal. The attack time is the trigger time for the limiter to begin compression when the audio signal exceeds the threshold. The release time is the duration for the audio signal to transition from being compressed to not being compressed. The compression ratio specifies the amount of compression applied to the audio signal. The values of the threshold, attack time, release time, and compression ratio can vary according to the compression requirements of the audio signal, and are not limited to specific values here.

Step S12: Calculating the duration for which the power value of the first compressed signal equals the power threshold. Specifically, the processor 60 obtains the first compressed signal and the first power threshold from the first limiter 50 and calculates the duration for which the power value of the first compressed signal equals the power threshold.

Step S13: Determining whether the duration exceeds the time threshold. Specifically, the processor 60 determines whether the duration exceeds the time threshold to generate a determination result and, based on the determination result, decides whether to further compress the first compressed signal.

When the determination result indicates that the duration exceeds the time threshold, implying the speaker system operates at high power for a long time or at full power input, the first compressed signal needs further compression, and step S14 is executed next. If the determination result indicates that the duration does not exceed the time threshold, the speaker system operates normally, and further compression of the first compressed signal is not necessary; step S15 is executed next.

Step S14: Compressing the first compressed signal to generate the second compressed signal, then amplify and output the second compressed signal. Specifically, the processor 60 transmits the first compressed signal to the second limiter 70. The second limiter 70, based on the second compression threshold, decay rate, and hold time, compresses the first compressed signal to generate the second compressed signal. The dynamic range of the second compressed signal is smaller than the dynamic range of the first compressed signal, and the power value of the second compressed signal is less than or equal to the second power threshold, the second power threshold is lower than the first power threshold. In other words, the power value of the second compressed signal is less than that of the first compressed signal. The second limiter 70 then transmits the second compressed signal to the power amplifier 80, which amplifies and outputs the second compressed signal to the speaker based on the speaker's driving requirements.

Additionally, the second compression threshold is preset in the second limiter 70. When the power value of the second compressed signal decreases to the second power threshold, the processor 60 controls the second limiter 70 to stop compressing and maintain the output of the second compressed signal. When the signal level of the first compressed signal decreases, the processor stops determining whether the duration exceeds the time threshold.

Step S15: Amplifying and output the first compressed signal. Specifically, the power amplifier 80 obtains the first compressed signal from the first limiter 50 and amplifies and outputs the first compressed signal to the speaker based on the speaker's driving requirements.

This audio signal processing method not only protects the subwoofer system from damage caused by prolonged high-power operation but also does not affect the ability to output high dynamic signals in a short period.

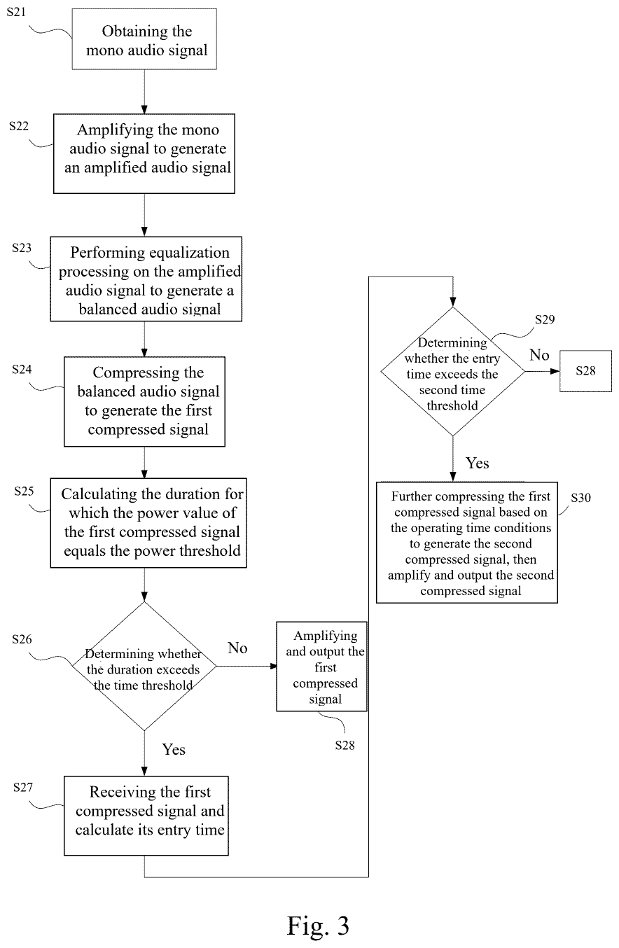

FIG. 3 illustrates the audio signal processing method according to an embodiment of the present application. As shown in FIG. 3, the audio signal processing method includes steps S21 to S30. Steps S25 to S26 are the same as steps S12 to S13 shown in FIG. 2, where the balanced audio signal is the audio signal, and the similarities between FIG. 3 and FIG. 2 will not be repeated here. Steps S21 to S23 further describe the generation of the balanced audio signal, while steps S28 to S29 further determine whether to activate the second limiter 70. Additionally, the time threshold in step S26 is for determining the duration, and the time threshold in step S29 is for determining the entry time. The time thresholds in steps S26 and S29 are not the same; to distinguish between them, the time threshold in step S26 is the first time threshold, and the time threshold in step S29 is the second time threshold. The following sections illustrate steps S21 to S23 and steps S27 to S30 using the audio signal processing device shown in FIG. 1.

Step S21: Obtaining the mono audio signal. As previously mentioned, the signal input interface 10 obtains the mono audio signal from an audio playback device; alternatively, the signal input interface 10 obtains the left channel audio signal and the right channel audio signal from the audio playback device, and the mixer 20 obtains the left channel audio signal and the right channel audio signal from the signal input interface 10 and generates the mono audio signal based on the left and right channel audio signals.

Step S22: Amplifying the mono audio signal to generate an amplified audio signal. As previously mentioned, the signal amplifier 30 obtains the mono audio signal from the signal input interface 10 or the mixer 20 and amplifies the mono audio signal, increasing its signal level and thereby increasing its amplitude. The amplified mono audio signal now has a higher signal level and greater amplitude compared to the original mono audio signal. The signal amplifier 30 then transmits the amplified audio signal to the equalizer 40.

Step S23: Performing equalization processing on the amplified audio signal to generate a balanced audio signal. Specifically, the equalizer 40 adjusts the amplified audio signal across multiple frequency bands by setting corresponding gain values. The equalizer 40 then adjusts the signal levels in these frequency bands based on the adjusted gain values, resulting in the balanced audio signal. The equalizer 40 transmits the balanced audio signal to the first limiter 50.

For example, there may be three frequency bands: low-frequency band, mid-frequency band, and high-frequency band. The low-frequency sound could be a piano, the mid-frequency sound could be a vocalist, and the high-frequency sound could be a flute. The equalizer 40 appropriately adjusts the three gain values corresponding to the low-frequency band, mid-frequency band, and high-frequency band of the amplified audio signal. After adjustment, these three gain values differ from each other, resulting in different signal levels for the amplified audio signal across the low-frequency, mid-frequency, and high-frequency bands. Through the adjustments made by the equalizer 40, the piano sound becomes richer, the singer's voice clearer, and the brightness of the flute sound is enhanced.

Step S24: Compressing the balanced audio signal to generate the first compressed signal. Specifically, the first limiter 50 compresses the balanced audio signal based on the first attack time, the first release time, the first threshold, and the first compression ratio. After compression, the maximum signal level of the balanced audio signal is below the first threshold. The compressed balanced audio signal is then considered the first compressed signal, which has a dynamic range smaller than the dynamic range of the balanced audio signal, and the power value of the first compressed signal is less than or equal to the first power threshold. Additionally, the first attack time, first release time, first threshold, and first compression ratio are preset in the first limiter 50.

Step S27: Receiving the first compressed signal and calculate its entry time. Specifically, the second limiter 70 receives the first compressed signal from the processor 60, and the processor 60 calculates the entry time of the first compressed signal into the second limiter 70.

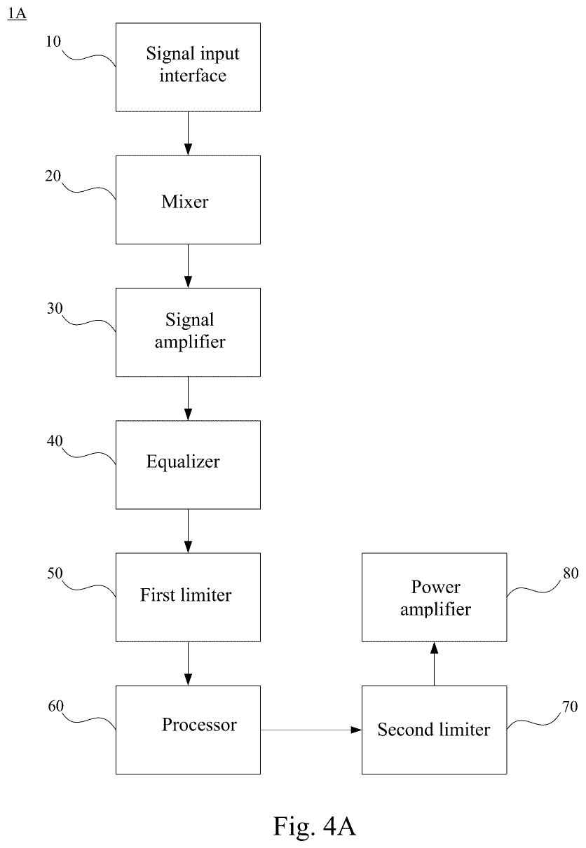

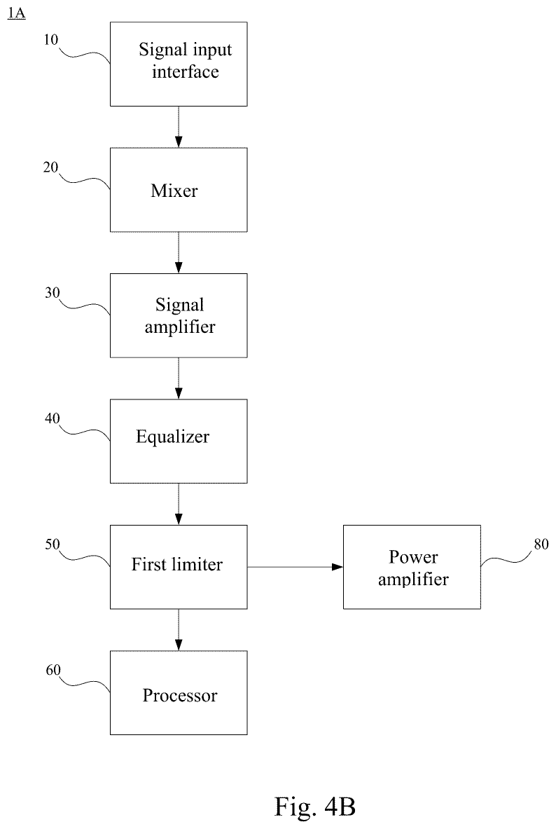

Step S28: Amplifying and output the first compressed signal. Specifically, as shown in FIG. 4B, the power amplifier 80 obtains the first compressed signal from the first limiter 50 and amplifies and outputs the first compressed signal to the speaker based on the speaker system's driving requirements.

Step S29: Determining whether the entry time exceeds the second time threshold. Specifically, the processor 60 determines whether the entry time exceeds the second time threshold to generate a second determination result and decides whether further compression of the first compressed signal is necessary based on the second determination result.

If the second determination result indicates that the entry time exceeds the second time threshold, implying the speaker system operates at high power for a long time or at full power input, the first compressed signal needs further compression. The processor 60 then activates the second limiter 70 and proceeds to step S30. If the second determination result indicates that the entry time does not exceed the second time threshold, further compression of the first compressed signal is not necessary, and the process returns to step S21.

Step S30: Further compressing the first compressed signal based on the operating time conditions to generate the second compressed signal, then amplify and output the second compressed signal. Specifically, as shown in FIG. 4A, the processor 60 transmits the first compressed signal and the operating time conditions to the second limiter 70. The operating time conditions include hold time and decay rate. The second limiter 70 compresses the first compressed signal based on the second compression threshold, decay rate, and hold time to generate the second compressed signal. The dynamic range of the second compressed signal is smaller than the dynamic range of the first compressed signal, and a power value of the second compressed signal less than or equal to the second power threshold, the second power threshold is lower than the first power threshold. In other words, the power value of the second compressed signal is lower than the power value of the first compressed signal. The second limiter 70 then transmits the second compressed signal to the power amplifier 80. The power amplifier 80 amplifies and outputs the second compressed signal to the speaker according to the driving requirements of the speaker system.

Additionally, the second compression threshold is preset in the second limiter 70. When the power value of the second compressed signal drops to the second power threshold, the processor 60 controls the second limiter 70 to stop compression and maintain the output of the second compressed signal. When the signal level of the mono audio signal is determined to decrease, the processor 60 stops determining whether the duration exceeds the first time threshold, and the power of the mono audio signal gradually returns to full power.

In this embodiment of the audio signal processing method, the first limiter 50 compresses the audio signal to adjust its maximum power over a short period. After the speaker system has been operating at full power for a certain duration, the second limiter 70 is activated to further compress the audio signal that has already been compressed by the first limiter 50. This causes the overall power of the speaker system to begin decreasing, ensuring that the speaker system can operate for extended periods at full power input without causing damage.

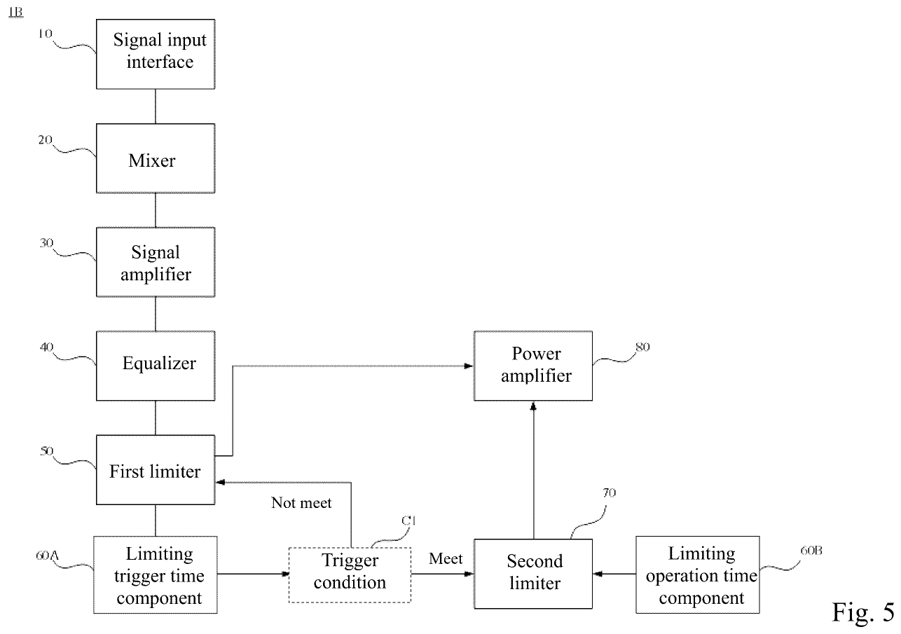

FIG. 5 is a block diagram of the audio signal processing device 1B according to another embodiment of the present application. As shown in FIG. 5, the audio signal processing device 1B includes a signal input interface 10, a mixer 20, a signal amplifier 30, an equalizer 40, a first limiter 50, a limiting trigger time component 60A, a limiting operation time component 60B, a second limiter 70, and a power amplifier 80. The configurations of the signal input interface 10, the mixer 20, the signal amplifier 30, the equalizer 40, the first limiter 50, the second limiter 70, and the power amplifier 80 are the same as those shown in FIG. 1 and are not repeated here.

The limiting trigger time component 60A and the limiting operation time component 60B are set in the processor 60, meaning they are functional units executed by the processor 60. The limiting trigger time component 60A is connected to the first limiter 50 and the second limiter 70; in other words, the limiting trigger time component 60A is positioned between the first limiter 50 and the second limiter 70. The limiting trigger time component 60A calculates the duration for which the power value of the first compressed signal equals the first power threshold and determines whether this duration exceeds the first time threshold. The first time threshold is defined as N seconds, and whether the duration exceeds N seconds serves as the trigger condition C1.

The limiting operation time component 60B is connected to the second limiter 70. In other words, the second limiter 70 is positioned between the limiting trigger time component 60A and the limiting operation time component 60B, and also between the limiting operation time component 60B and the power amplifier 80. The limiting operation time component 60B stores operating time conditions, calculates the entry time of the first compressed signal into the second limiter 70, and determines whether the entry time exceeds the second time threshold.

An electronic audio playback device provides left channel audio signals and right channel audio signals to the mixer 20, wherein the electronic audio playback device may be a portable playback device such as a CD player, mobile phone, microphone, or broadcasting system. The mixer 20 combines the left channel audio signal and right channel audio signal into a mono audio signal and transmits the mono audio signal to the signal amplifier 30. The signal amplifier 30 amplifies the signal level of the mono audio signal to an appropriate value through gain adjustment and transmits the amplified mono audio signal to the equalizer 40. The equalizer 40 performs an equalization process on the amplified mono audio signal to produce a balanced audio signal. The first limiter 50 receives the balanced audio signal from the equalizer 40 and compresses the balanced audio signal to produce the first compressed signal. The power of the first compressed signal is limited within the design power range of the first limiter 50.

The limiting trigger time component 60A then calculates the duration for which the power value of the first compressed signal equals the first power threshold and determines whether the duration meets trigger condition C1. When the limiting trigger time component 60A determines that the duration does not meet trigger condition C1, it outputs the first compressed signal to the power amplifier 80, which amplifies and outputs the first compressed signal to the speaker. When the limiting trigger time component 60A determines that the duration meets trigger condition C1, it outputs the first compressed signal to the second limiter 70. The limiting operation time component 60B calculates the entry time of the first compressed signal into the second limiter 70 and determines whether the entry time exceeds the second time threshold. If the entry time exceeds the second time threshold, the second limiter 70 is activated and compresses the first compressed signal according to the operating time conditions of the limiting operation time component 60B to generate a second compressed signal, reducing its power. When the power of the second compressed signal decreases to the conditions set by the second limiter 70, the second limiter 70 stops compressing and maintains the output of the second compressed signal. If the signal level of the left channel audio signal or right channel audio signal decreases, the limiting trigger time component 60A is turned off, and the power of the signal output by the power amplifier 80 gradually returns to the full power state.

This embodiment of the audio signal processing device utilizes the configuration of the limiting trigger time component 60A, the limiting operation time component 60B, and the second limiter 70 to protect subwoofer systems from damage caused by prolonged high-power operation, while not affecting the output capability of large dynamic signals over a short duration.

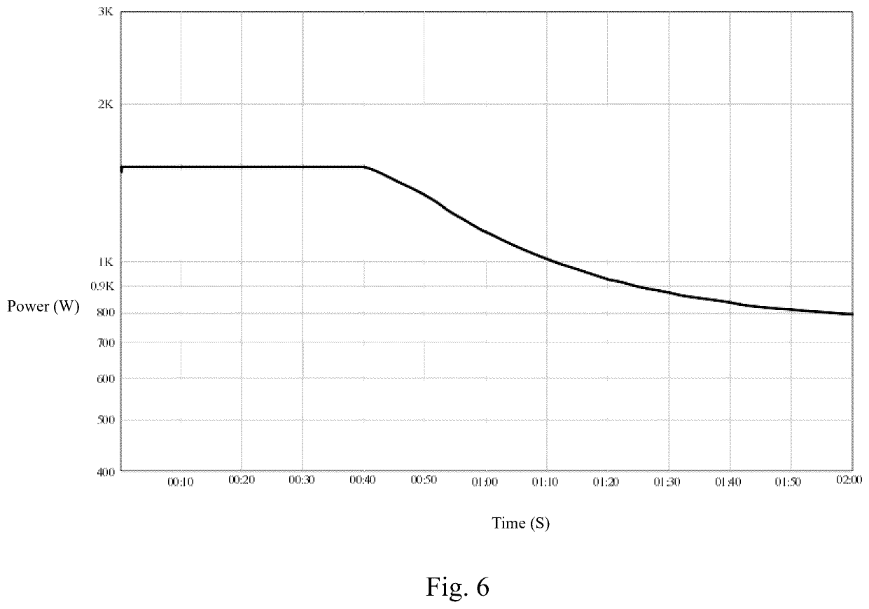

FIG. 6 is a schematic diagram illustrating the reduction of audio signal power by the second limiter according to an embodiment of the present application. As shown in FIG. 6, and in conjunction with FIG. 1, the power of the speaker system is approximately 1600 W between zero and 40 seconds. After 40 seconds, the second limiter 70 is triggered, causing the power of the speaker system to gradually decrease and reach 800 W in 2 minutes. When 1600 W represents the full power of the speaker system, the power of the speaker system decreases to half of the full power in 2 minutes. Thus, through the audio signal processing method and audio signal processing device of the present application, it ensures that the speaker system can operate continuously at full power without damaging the speaker and power amplifier, maintaining normal operation and providing better protection and user experience.

In summary, the audio signal processing method and audio signal processing device of the present application, by configuring two limiters, reduce excessively loud sounds and prevent damage to electronic components when the speaker system runs at maximum power for extended periods.

Additionally, the audio signal processing method and the audio signal processing device of the present application can be applied to subwoofer systems. Even when the subwoofer system operates at high power for extended periods, the audio signal processing method and the audio signal processing device of the present application can prevent damage to the speakers and power amplifier caused by high power operation, while not affecting the output capacity of large dynamic signals over short periods.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present invention is intended to be dedicated to the public regardless of whether the element or component is explicitly recited in the following claims.

What is claimed is:

1. An audio signal processing method, comprising:
obtaining an audio signal and compressing the audio signal to generate a first compressed signal, wherein a power value of the first compressed signal is less than or equal to a first power threshold;
calculating a duration for which the power value of the first compressed signal is equal to the first power threshold;
determining whether the duration exceeds a time threshold; and
compressing the first compressed signal to generate a second compressed signal when the duration exceeds the time threshold, wherein a power value of the second compressed signal is less than or equal to a second power threshold, and the second power threshold is less than the first power threshold.

2. The audio signal processing method as claimed in claim 1, further comprising amplifying and outputting the first compressed signal when the duration does not exceed the time threshold.

3. The audio signal processing method as claimed in claim 1, wherein compressing the audio signal to generate the first compressed signal comprises compressing the audio signal according to a first compression threshold and a first compression ratio to generate the first compressed signal, and
wherein a dynamic range of the first compressed signal is less than a dynamic range of the audio signal.

4. The audio signal processing method as claimed in claim 1, wherein the time threshold is a first time threshold, and when the duration exceeds the first time threshold, said compressing the first compressed signal to generate the second compressed signal comprises:
receiving the first compressed signal and calculating an entry time of the first compressed signal when the duration exceeds the first time threshold;
determining whether the entry time exceeds a second time threshold; and
compressing the first compressed signal according to an operation time condition to generate the second compressed signal and amplifying and outputting the second compressed signal when the entry time exceeds the second time threshold.

5. The audio signal processing method as claimed in claim 4, wherein the operation time condition includes a hold time and a decay rate, and said compressing the first compressed signal according to the operation time condition to generate the second compressed signal comprises compressing the first compressed signal according to a second compression threshold, the decay rate, and the hold time to generate the second compressed signal, and
wherein a dynamic range of the second compressed signal is less than a dynamic range of the first compressed signal.

6. The audio signal processing method as claimed in claim 1, further comprising:
obtaining a mono audio signal;
amplifying the mono audio signal to generate an amplified audio signal; and
performing an equalization process on the amplified audio signal to generate a balanced audio signal, wherein the balanced audio signal is the audio signal.

7. The audio signal processing method as claimed in claim 6, wherein obtaining the mono audio signal comprises:
obtaining a left channel audio signal and a right channel audio signal; and
mixing the left channel audio signal and the right channel audio signal to generate the mono audio signal.

8. The audio signal processing method as claimed in claim 6, further comprising stopping the determination of whether the duration exceeds the time threshold when the signal level of the mono audio signal decreases.

9. An audio signal processing device, comprising:
a first limiter configured to obtain an audio signal and compress the audio signal to generate a first compressed signal, wherein a power value of the first compressed signal is less than or equal to a first power threshold;
a limiting trigger time component, connected to the first limiter, configured to calculate a duration during which the power value of the first compressed signal is equal to the first power threshold, and determine whether the duration exceeds a time threshold;
a second limiter, connected to the limiting trigger time component, configured to compress the first compressed signal to generate a second compressed signal when the limiting trigger time component determines that the duration exceeds the time threshold, wherein a power value of the second compressed signal is less than or equal to a second power threshold, and the second power threshold is less than the first power threshold; and
a power amplifier, connected to the second limiter and the first limiter, configured to amplify and output the second compressed signal.

10. The audio signal processing device as claimed in claim 9, wherein the power amplifier amplifies and outputs the first compressed signal when the processor determines that the duration is not greater than the time threshold.

11. The audio signal processing device as claimed in claim 9, wherein compressing the audio signal to generate the first compressed signal by the first limiter comprises compressing the audio signal according to a first compression threshold and a first compression ratio to generate the first compressed signal, and
wherein a dynamic range of the first compressed signal is smaller than a dynamic range of the audio signal.

12. The audio signal processing device as claimed in claim 9, further comprising a limiting operation time component,
wherein the limiting trigger time component is connected to the second limiter and stores an operation time condition, and the time threshold is a first time threshold,
wherein when the limiting trigger time component determines that the duration is greater than the first time threshold, the second limiter receives the first compressed signal, the limiting operation time component calculates an entry time of the first compressed signal into the second limiter, and determines whether the entry time is greater than a second time threshold, and
wherein when the limiting operation time component determines that the entry time is greater than the second time threshold, the second limiter is activated and obtains the operation time condition from the limiting operation time component, and compresses the first compressed signal according to the operation time condition to generate the second compressed signal.

13. The audio signal processing device as claimed in claim 12, wherein the operation time condition comprises a hold time and a decay rate, and compressing the first compressed signal by the second limiter according to the operation time condition to generate the second compressed signal comprises compressing the first compressed signal according to a second compression threshold, the decay rate, and the hold time to generate the second compressed signal, and
wherein a dynamic range of the second compressed signal is smaller than a dynamic range of the first compressed signal.

14. The audio signal processing device as claimed in claim 12, wherein the limiting trigger time component and the limiting operation time component are disposed in the processor.

15. The audio signal processing device as claimed in claim 9, further comprising:
a signal input interface configured to obtain a mono audio signal;
a signal amplifier connected to the signal input interface and configured to amplify the mono audio signal to generate an amplified audio signal; and
an equalizer connected to the signal amplifier and the first limiter, and configured to execute an equalization process on the amplified audio signal to generate and transmit the balanced audio signal to the first limiter,
wherein the balanced audio signal is the audio signal.

16. The audio signal processing device as claimed in claim 15, further comprising a connected to the signal input interface and the signal amplifier,
wherein the signal input interface obtains a left channel audio signal and a right channel audio signal from an audio playback device, and
wherein the mixer mixes the left channel audio signal and the right channel audio signal to form the mono audio signal, and transmits the mono audio signal to the signal amplifier.

17. The audio signal processing device as claimed in claim 15, wherein, when a signal level of the mono audio signal drops, the limiting trigger time component is turned off and stops determining whether the duration is greater than the time threshold.
